(19) United States
(12) Patent Application Publication
(10) Pub. No.: US 2015/0380552 A1
(43) Pub. Date: Dec. 31, 2015

(54) TRANSISTOR STRUCTURE AND METHOD FOR MANUFACTURING THE SAME

(71) Applicant: National Applied Research Laboratories, Taipei City (TW)

(72) Inventors: Wen-Hsien TU, New Taipei (TW); Chee-Wee LIU, Taipei (TW)

(21) Appl. No.: 14/315,821

(22) Filed: Jun. 26, 2014

(51) Int. Cl. H01L 29/78; H01L 29/423; H01L 27/092; H01L 29/267; H01L 29/49

(52) U.S. Cl. CPC H01L 29/7841; H01L 29/267; H01L 29/495; H01L 29/4966; H01L 27/092; H01L 29/42356

(57) ABSTRACT

A transistor structure is provided to reduce the sizes of a semiconductor device applying the transistor structure and maximize the performance of the semiconductor device, wherein the transistor structure comprises a substrate, a first semiconductor layer, a second semiconductor layer and a first gate structure. The first semiconductor layer that is formed on the substrate has a first space by which the first semiconductor layer is divided into a first region and a second region. The second semiconductor layer that is formed on the substrate and stacked on the first semiconductor layer comprises a first source region stacked on the first region, a first drain region stacked on the second region, a first floating structure crossing the first space and connected between the first source region and the first drain region. The first gate structure surrounds the first floating structure.

### FIELD OF THE INVENTION

The present invention relates to a semiconductor device and the method for fabricating the same, and more particularly to a transistor structure and the fabricating method thereof.

### BACKGROUND OF THE INVENTION

As semiconductor devices become more highly integrated, the critical feature size of semiconductor devices continues to shrink. For example, a gate length of a metal-oxide-semiconductor (MOS) transistor may decrease as the semiconductor devices require more MOS transistors. As the gate length of the MOS transistors decreasing, the channel length thereof may also decrease, and short channel effects that degrade the charge controllability of the gate biasing of the MOS transistors may be more likely exhibited. As a result, controlling the MOS transistors becomes more difficult, off-state current of the MOS transistors may increase due to the short channel effect, and the reliability of the transistor is thus degraded.

To solve the problems, three-dimensional devices, for example a semiconductor device having a GAA transistor structure has been developed in order to reduce the size of the MOS transistors formed on the semiconductor substrate, and also maximizes the performance of the semiconductor device.

According to the GAA transistor structure of the semiconductor device, a gate electrode is formed to surround a channel covered with a gate insulation layer, wherein the entire peripheral portion of the channel surrounded by the gate electrode can be used as a channel, and thus, the effective channel width is increased, the short channel effects, which cause problems in a conventional planar MOS transistor, may be prevented (or reduced).

However, in order to form the GAA transistor structure and involving more MOS transistors in the semiconductor device, a complex fabrication procedure is required as compared to the process for fabricating a semiconductor device applying conventional planar MOS transistors. Therefore, there is a need of providing an improved GAA transistor structure and the method for fabricating the same to obviate the drawbacks encountered from the prior art.

### SUMMARY OF THE INVENTION

In accordance with one aspect of the present invention, a transistor structure is provided to reduce the sizes of a semiconductor device applying the transistor structure and maximize the performance of the semiconductor device, wherein the transistor structure comprises a substrate, a first semiconductor layer, a second semiconductor layer and a first gate structure. The first semiconductor layer that is formed on the substrate has a first space by which the first semiconductor layer is divided into a first region and a second region. The second semiconductor layer that is formed on the substrate and stacked on the first semiconductor layer comprises a first source region stacked on the first region, a first drain region stacked on the second region, a first floating structure crossing the first space and connected between the first source region and the first drain region. The first gate structure surrounds the first floating structure.

In one embodiment of the present invention, the transistor structure further comprises a second gate structure, wherein the second semiconductor layer further comprises a third region and a fourth region divided by a second space; the first semiconductor layer further comprises a second source region stacked on the third region, a second drain region stacked on the fourth region and a second floating structure crossing the second space and connected between the second source region and the second drain region; and wherein the second gate structure surrounds the second floating structure.

In one embodiment of the present invention, the transistor structure further comprises a third semiconductor layer stacked on the second semiconductor layer, a fourth semiconductor layer stacked on the third semiconductor layer, wherein the third semiconductor layer has a fifth region and a sixth region divided by a third space, the fourth semiconductor layer has a third source region stacked on the fifth region a third drain region stacked on the sixth region and a third floating structure crossing the third space and connected between the third source region and the third drain region, and the first gate structure surrounds the third floating structure.

In accordance with another aspect, the present invention provides a method for fabricating a transistor structure to simplified the manufacturing process and reduce the manufacturing cost, wherein the method comprises steps as follows: Firstly, a substrate is provided and a stacked structure comprising a first semiconductor layer and a second semiconductor layer is then formed on the substrate. Next, the first semiconductor layer is partially removed to form a first space, so as to divide the first semiconductor layer into a first region and a second region; and the second semiconductor layer is then partially removed to form a first floating structure crossing the first space, a first source region stacking on the first region, and a first drain region stacking on the second region, wherein the first floating structure is connected between the first source region and the first drain region. Subsequently, a first gate structure is formed to surround the first floating structure.

In one embodiment of the present invention, the method for fabricating the transistor structure further comprises steps of partially removing a remaining portion of the second semiconductor layer to form a second space dividing the remaining portion of the second semiconductor layer into a third region and a fourth region; partially removing a remaining portion of the first semiconductor layer to form a second floating structure crossing the second space, a second source region stacking on the third region, and a second drain region stacking on the fourth region, wherein the second floating structure is connected between the second source region and the second drain region; and forming a second gate structure surrounding the second floating structure.

In one embodiment of the present invention, the method for fabricating the transistor structure further comprises steps of forming a third semiconductor layer stacked on the second semiconductor layer and forming a fourth semiconductor layer stacked on the third semiconductor layer, wherein the third semiconductor layer is partially removed by the step of partially removing the first semiconductor layer to form a third space dividing the third semiconductor layer into a fifth region and a sixth region; and the fourth semiconductor layer is partially removed by the step of partially removing the second semiconductor layer to form a third floating structure crossing the third space, a third source region stacking on the fifth region, and a third drain region stacking on the sixth region, wherein the third floating structure is connected between the third source region and the third drain region; and the third floating structure is surrounded by the first gate structure.

In accordance with the aforementioned embodiments of the present invention, a transistor structure having at least one MOS transistor is provided. The process for fabricating the transistor structure comprises steps as follows: Firstly, a stacked structure constituted by a first semiconductor layer and a second semiconductor layer stacked in sequence is formed on a substrate. The first semiconductor layer is then partially removed to at least form a first space dividing the first semiconductor layer into a first region from a second region. Subsequently, the second semiconductor layer is also partially removed to form a source region stacked on the first region, a drain region stacked on the second region and a floating structure crossing the first space. Next, a first gate structure surrounding the first floating structure is formed. Since each MOS transistor involved in the transistor structure can be formed merely by steps of patterning two semiconductor layers formed and stacked in sequence on the subtract and performing a gate structure deposition process without applying a silicon on insulator (SOI) substrate, thus it is not requiring a complex procedure as compared to that for fabricating a conventional transistor structure. Such that, the process for fabricating the transistor structure can be simplified and the manufacturing cost thereof can be reduced.

In addition, another MOS transistor also formed in the first semiconductor layer and the second semiconductor layer may be further involved in the transistor structure by performing a similar fabricating process, and still another or more MOS transistor aligning to these two MOS transistors formed in the stacked structure can be further formed in other semiconductor layers stacked on the stacked structure simultaneous to the fabricating process for fabricating the underlying MOS transistor. As a result, more MOS transistors can be further integrated in the transistor structure by the simplified and less expense manufacturing process.

### BRIEF DESCRIPTION OF THE DRAWINGS

The above objects and advantages of the present invention will become more readily apparent to those ordinarily skilled in the art after reviewing the following detailed description and accompanying drawings, in which:

FIGS. 1A-1F are perspective views of the processing structures illustrating a method for fabricating a transistor structure in accordance with one embodiment of the present invention;

FIGS. 1A′-1F′ are cross-sectional views taken along the cross-sectional line S1 of the FIGS. 1A-1F;

FIGS. 2A-2F are perspective views of the processing structures illustrating a method for fabricating a transistor structure in accordance with another embodiment of the present invention;

FIGS. 2A′-2F′ are cross-sectional views taken along the cross-sectional line S2 of the FIGS. 2A-2G.

FIGS. 3A-3F are perspective views of the processing structures illustrating a method for fabricating a transistor structure in accordance with still another embodiment of the present invention;

FIGS. 3A′-3F′ are cross-sectional views taken along the cross-sectional line S3 of the FIGS. 3A-3F; and

FIG. 4 is a perspective view of a transistor structure in accordance with still another embodiment of the present invention.

### DETAILED DESCRIPTION OF PREFERRED EMBODIMENTS

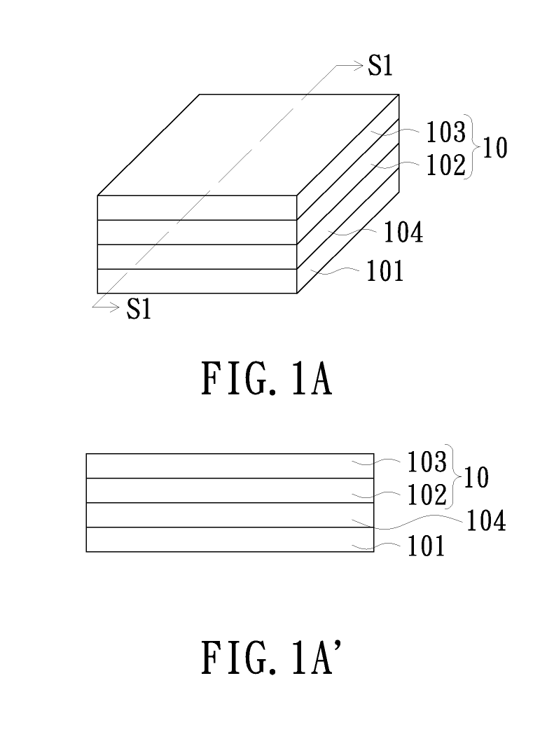

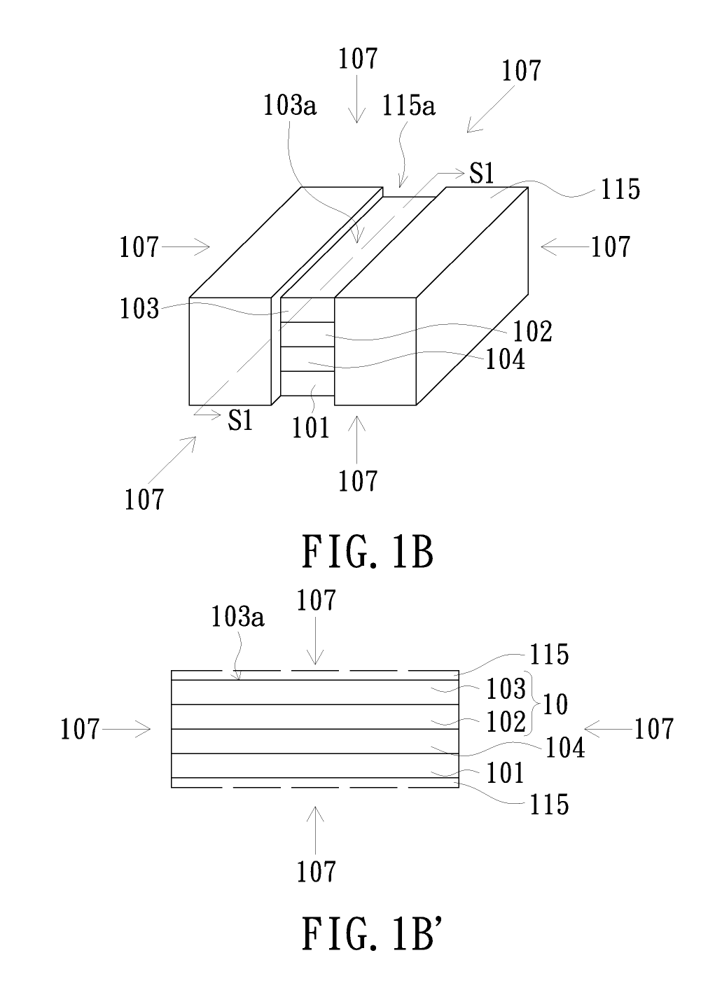

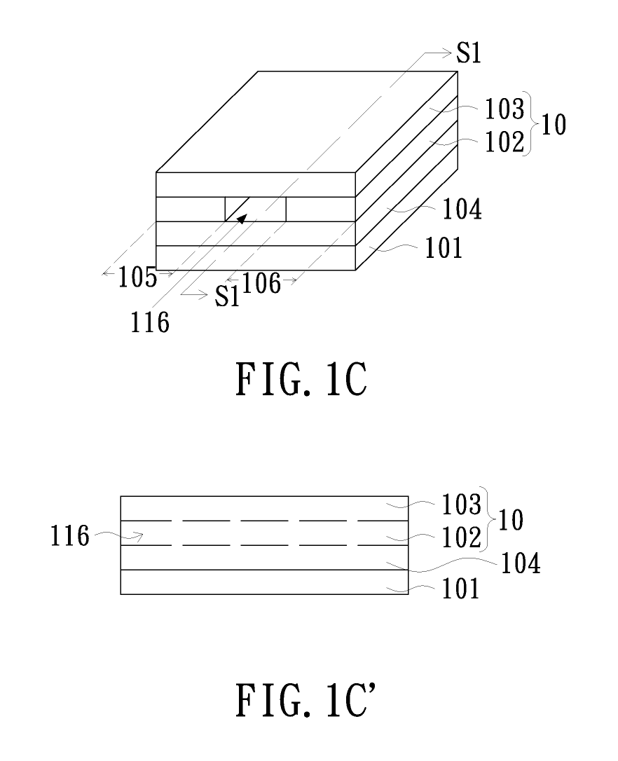

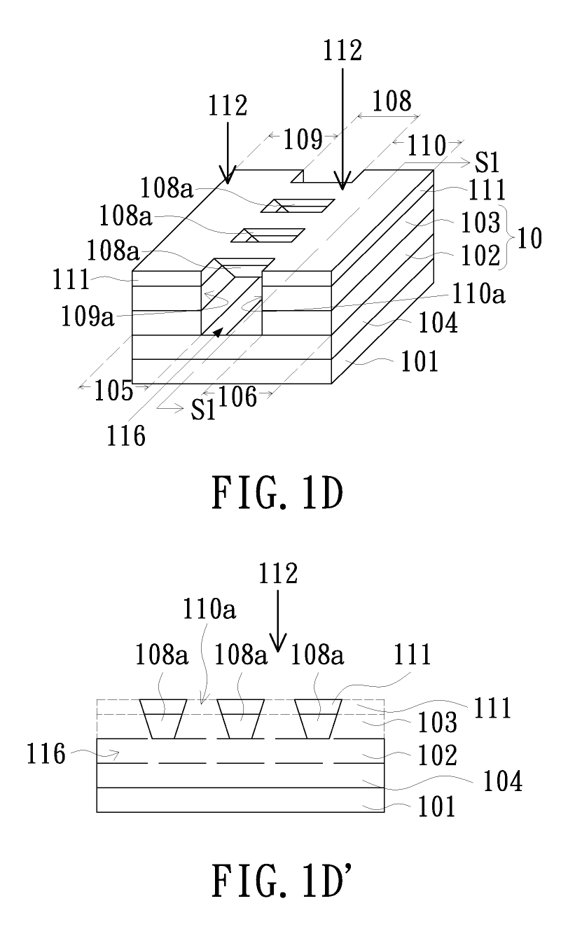

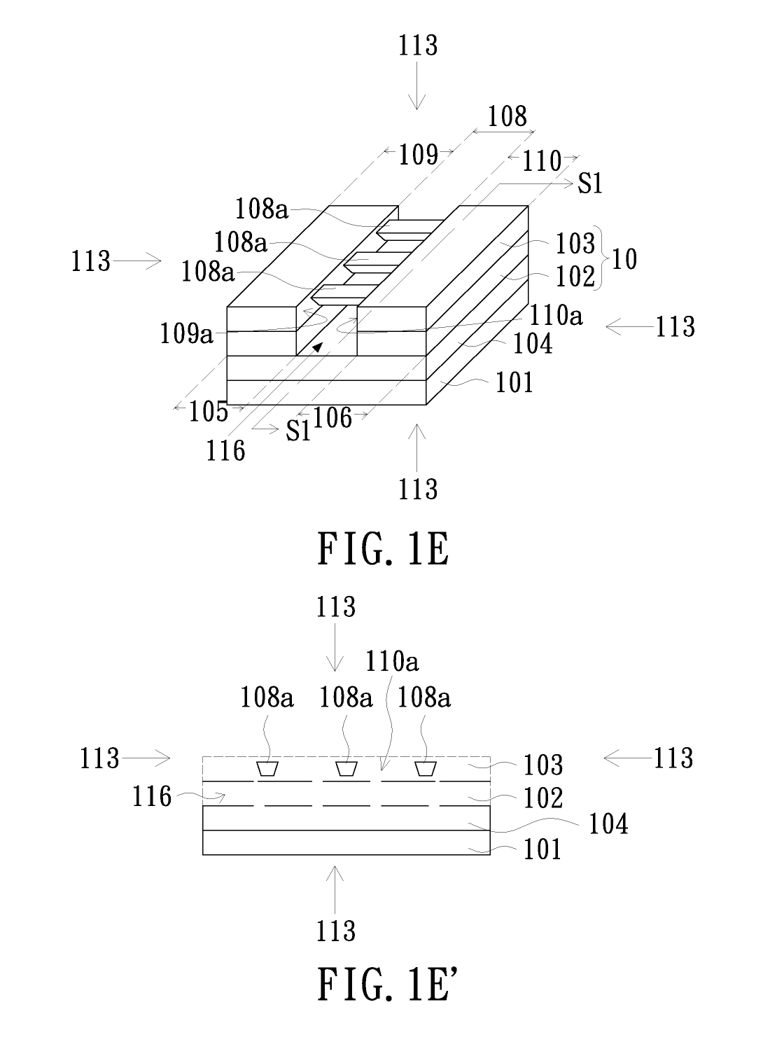

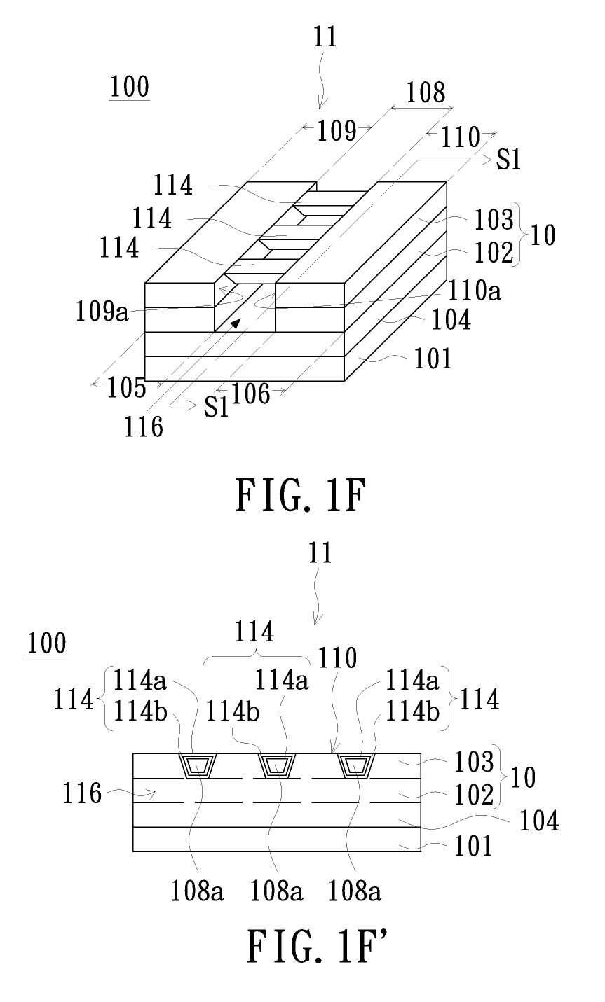

FIGS. 1A-1F are perspective views of the processing structures illustrating a method for fabricating a transistor structure 100 in accordance with one embodiment of the present invention, FIGS. 1A′-1F′ are cross-sectional views taken along the cross-sectional line 51 of the FIGS. 1A-1F.

The method comprises steps as follows. Firstly, a substrate 101 is provided and a stacked structure 10 comprising a first semiconductor layer 102 and a second semiconductor layer 103 is then formed on the substrate 101 (see FIG. 1A and FIG. 1A′).

In some embodiments of the present invention, the substrate 101 may be a silicon substrate, a SOI substrate, a glass substrate, a plastic substrate or a sapphire substrate. In the present embodiments, the substrate 101 is a silicon substrate, and prior to the forming of the stacked structure 10, a buffer layer 104 is formed on the substrate 101, wherein the buffer layer 104 is a germanium (Ge) epitaxial film.

The first semiconductor layer 102 and the second semiconductor layer 103 are epitaxial layers having a lattice matched interface or a lattice mismatched interface formed by an epitaxial growth process. In some embodiments of the present invention, the presence of the lattice mismatched interface formed between the first semiconductor layer 102 and the second semiconductor layer 103 may serve as a relaxed layer either providing tensile strain for n-type MOS transistors or providing compressive strain for p-type MOS transistors of the transistor structure, so as to enhance the performance of the transistor structure.

In some embodiments of the present invention, the first semiconductor layer 102 has a p-type conductivity, and the second semiconductor layer 103 has an n-type conductivity. For example the first semiconductor layer 102 may be made of germanium (Ge) or Ge-based phase-change materials including germanium antimonide (GeSb) or germanium telluride (GeTe), and the second semiconductor layer 103 is made of an III-V compound semiconductor materials, such as gallium arsenide (GaAs), gallium indium arsenide (InGaAs) or the like. In the present embodiment, and the second semiconductor layer 103 is made of Ge and the second semiconductor layer 103 is made of the GaAs.

Next, the first semiconductor layer 102 is partially removed to form a first space 116 in a manner of dividing the first semiconductor layer 102 into a first region 105 and a second region 106. In the present embodiment, a patterned photoresist layer 115 having a slot opening 115a is formed to partially encapsulate the stacked structure 10 that is constituted by the first semiconductor layer 102 and the second semiconductor layer 103, whereby a top surface 103a of the second semiconductor layer 103 and portions of sidewalls of the first semiconductor layer 102 and the second semiconductor layer 103 are exposed through the slot opening 115a (see FIG. 1B and FIG. 1B′).

A wet etching process 107 (see FIG. 1B and FIG. 1B′) having a high selectivity between the first semiconductor layer 102 and the second semiconductor layer 103 is then performed to remove a portion of the first semiconductor layer 102. In the present embodiment, an etchant having an etching rate for removing the first semiconductor layer 102 greater than that for removing the second semiconductor layer 103 is applied for performing the wet etching process 107, whereby the portion of the first semiconductor layer 102 that is not encapsulated by the patterned photoresist layer 115 is removed, so as to form a tunnel (the first space 116) passing through the stack structure 10 and dividing the first semiconductor layer 102 into a first region 105 and a second region 106 (see FIG. 1C and FIG. 1C′).

Subsequently, the second semiconductor layer 103 is then partially removed to form a first floating structure 108 crossing the first space 116, a first source region 109 stacking on the first region 105, and a first drain region 110 stacking on the second region 106, wherein the first floating structure 108 connects the first source region 109 and the first drain region 110.

In the present embodiment, a patterned photoresist layer 111 is formed to partially cover the stacked structure 10 and expose portions of the top surface 103a of the second semiconductor layer 103 that are overlapped with the first space 116. An anisotropic etching process 112, such as a reactive ion etch (RIE) process or other dry etching process, is then performed to remove the portion of the second semiconductor layer 103 that are not covered by the patterned photoresist layer 111, whereby the second semiconductor layer 103 is divided into the first floating structure 108, the first source region 109 and the first drain region 110. In the present embodiment, the first floating structure 108 comprises a plurality of bridge portions 108a laterally extending from a sidewall 109a of the first source region 109 crossing the first space 116 to connect to a side wall 110a of the first drain region 110 (see FIG. 1D and FIG. 1D′). In some embodiments of the present invention, each of the bridge portions 108a may have a triangular cross-section, a rectangular cross-section or a trapezoidal cross-section. In the present embodiment, each of the bridge portions 108a has a trapezoidal cross-section.

In some embodiments of the present invention, after the anisotropic etching process 112 is carried out, an over etching process 113 is performed to remove a portion of the first floating structure 108. In the present embodiment, the over etching process 113 preferably is an isotropic etching process, and each of the bridge portions 108a may be annularly thinned down by the over etching process 113. In other words, the diameter of the bridge portions 108a can be reduced after the over etching process 113 is carried out, and each of the bridge portions 108a may not vertically extends beyond the sidewall 109a of the first source region 109 and the side wall 110a of the first drain region 110 (see FIG. 1E and FIG. 1E′).

In the present invention, the over etching process 113 may improve the performance of the transistor structure 100, when there is a lattice mismatched interface formed between the first semiconductor layer 102 and the second semiconductor layer 103, since the over etching process 113 can remove a portion of the second semiconductor layer 103 having the lattice mismatched interface that may provide compressive strain and retard electron migrating through the bridge portions 108a serving as channels of the transistor structure 100.

Subsequently, a first gate structure 114 is formed to surround the first floating structure 108, wherein the present invention, the first gate structure 114 comprises a gate dielectric layer 114a and a gate electrode layer 114b. For example, the gate dielectric layer 114a may be a high-k dielectric layer and the gate electrode layer 114b may be a metal or conductive compound layer. In the present embodiment, an atomic layer deposition (ALD) process (not shown) is performed to form a germanium dioxide (GeO₂) layer, an aluminum oxide (Al₂O₃) layer and a titanium nitride (TiN) layer stacking in sequence and surrounding each of the bridge portions 108a of the first floating structure 108, wherein the GeO₂ layer serves as a buffer layer, the Al₂O₃ layer serves as the gate dielectric layer 114a and the TiN layer serves as the gate electrode layer 114b.

After the first gate structure 114 is formed, at least one doping process (not shown) is performed to implant a plurality of n-type dopants, such as phosphorus (P) ions or arsenic (As) ions, into the first source region 109 and the first drain region 110, meanwhile the transistor structure 100 having an n-type MOS transistor 11 is formed (see FIG. 1F and FIG. 1F′).

Although the transistor structure 100, in the present embodiment, merely comprises an n-type MOS transistor 11 constituted by the first source region 109, the first drain region 110 and the first gate structure 114, more MOS transistors may be involved in the transistor structure 100.

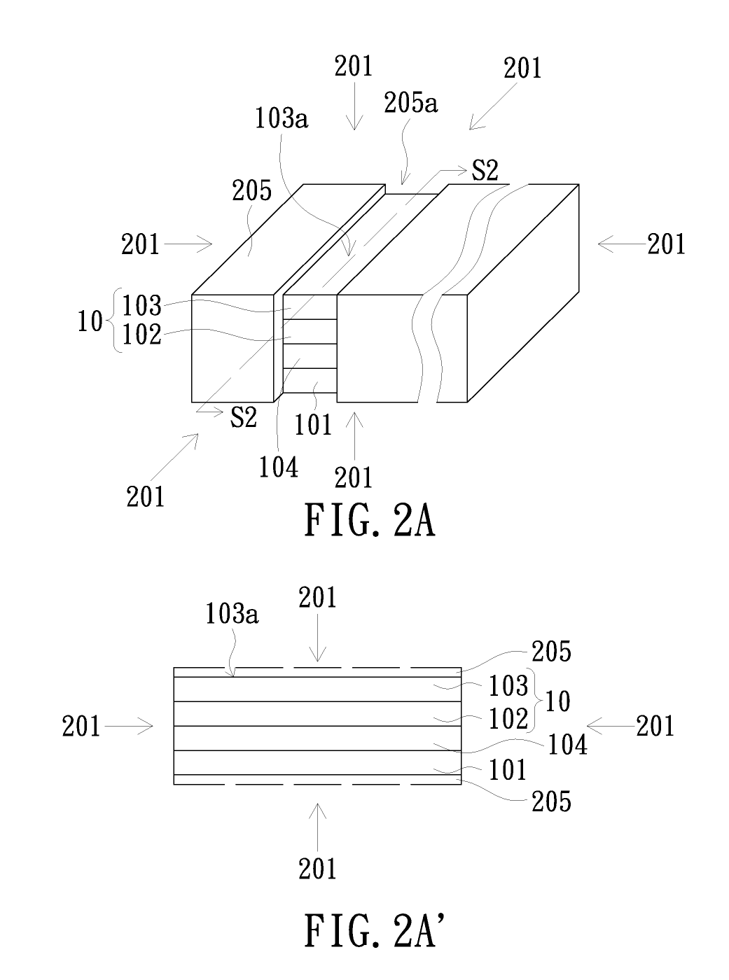

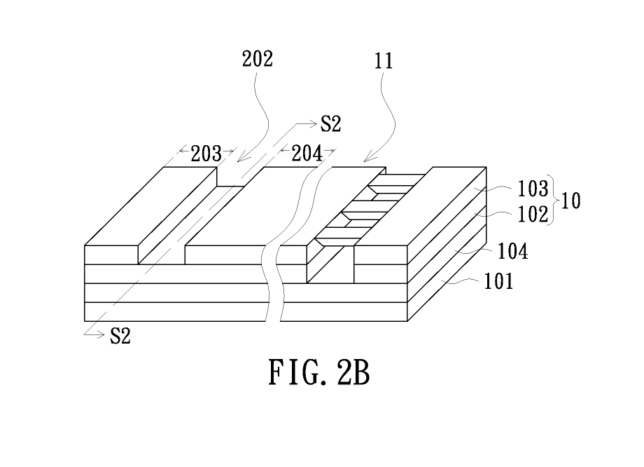

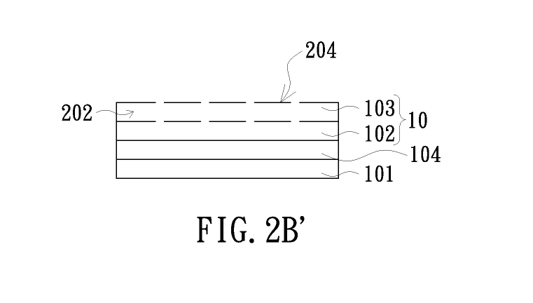

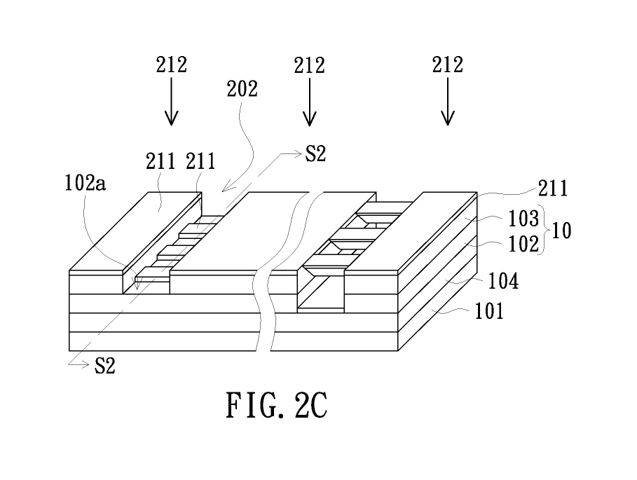

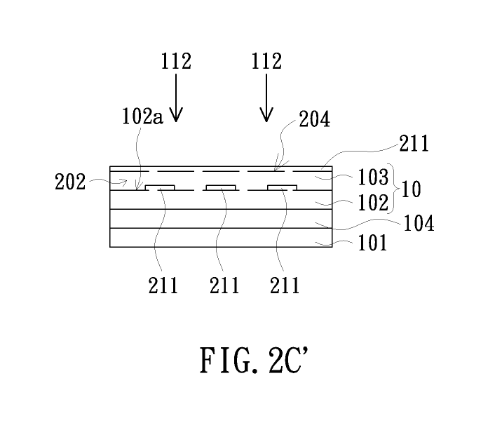

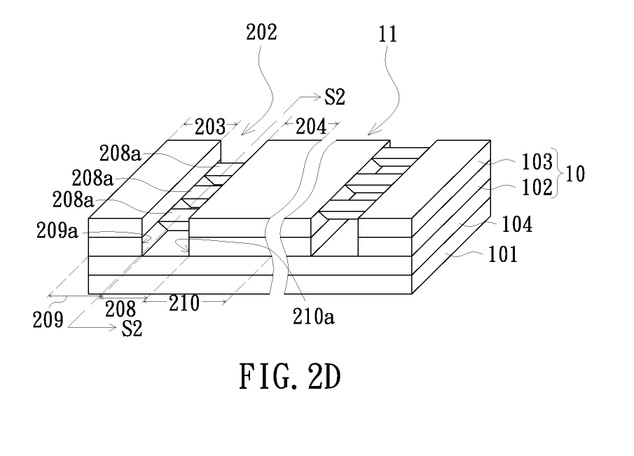

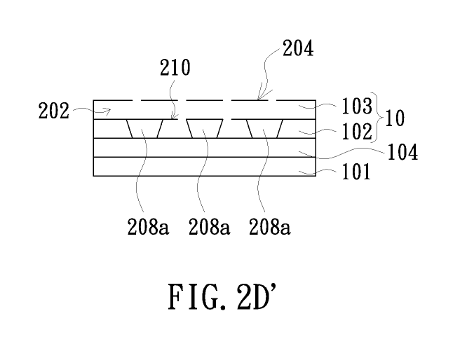

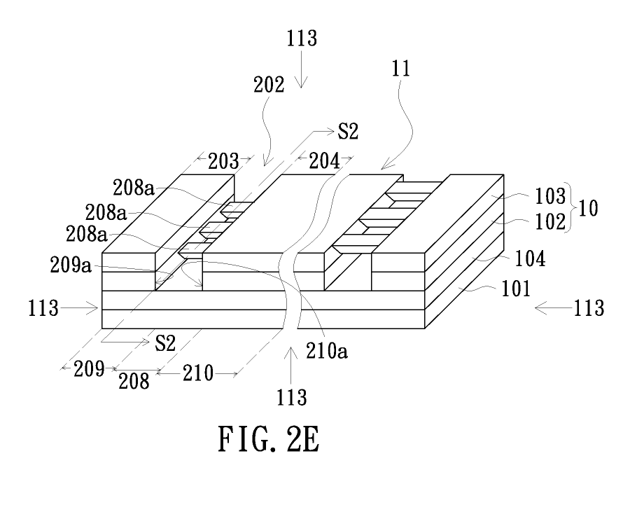

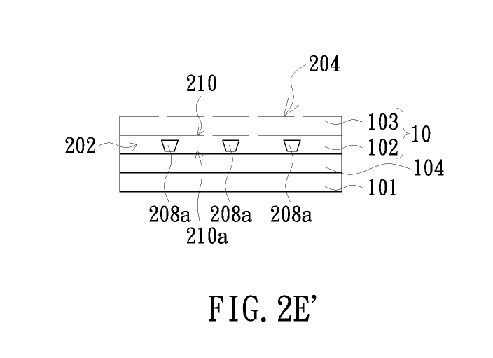

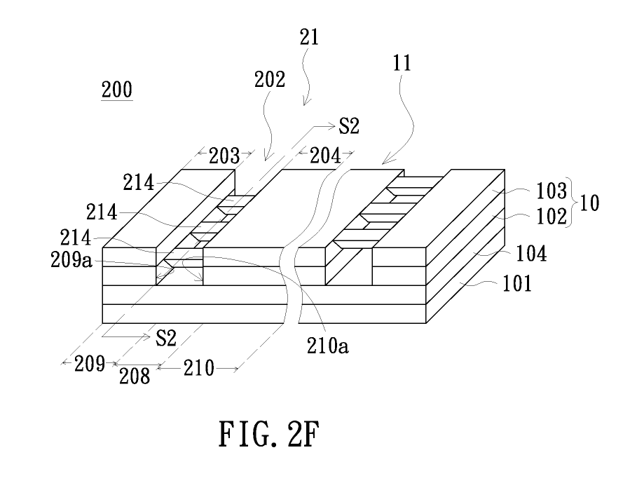

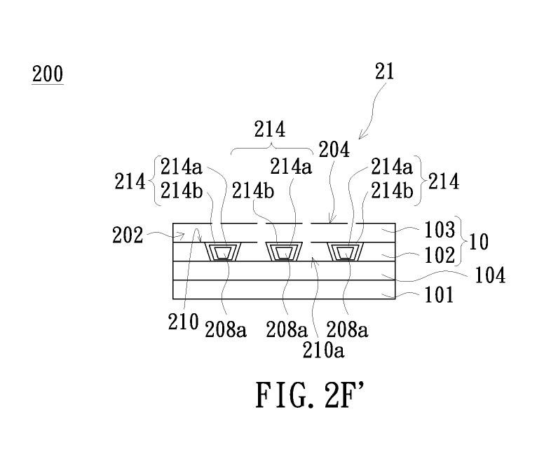

FIGS. 2A-2F are perspective views of the processing structures illustrating a method for fabricating a transistor structure 200 in accordance with another embodiment of the present invention. FIGS. 2A′-2F′ are cross-sectional views taken along the cross-sectional line S2 of the FIGS. 2A-2G. The structure of the transistor structure 200 is similar to that of the transistor structure 100 except that the transistor structure 200 further comprises a p-type MOS transistor 12 formed in the first semiconductor layer 102 and the second semiconductor layer 103 adjacent to the n-type MOS transistor 11. Thus the similar elements are illustrated by similar reference numbers and the identical process both applied for fabricating the transistor structures 100 and 200 will not be redundantly described therein.

For example, in the present embodiment, the process for fabricating the transistor structure 200 continues from the FIG. 1F and further comprises steps as follows. Firstly, an etching process 201 is performed to further pattern the remaining portion of the second semiconductor layer 103, so as to form a second space 202 dividing the remaining portion of the second semiconductor layer 103 into a third region 203 and a fourth region 204.

In the present embodiment, a patterned photoresist layer 205 having a slot opening 205a is formed to encapsulate the n-type MOS transistor 11 (not shown) and portions of the remaining first semiconductor layer 102 and the remaining second semiconductor layer 103, whereby a top surface 103a of the second semiconductor layer 103 and portions of sidewalls of the first semiconductor layer 102 and the second semiconductor layer 103 are exposed through the slot opening 205a (see FIG. 2A and FIG. 2A′).

A wet etching process 201 having a high selectivity between the first semiconductor layer 102 and the second semiconductor layer 103 is then performed to remove a portion of the remaining second semiconductor layer 103 (see FIG. 2A and FIG. 2A′). In the present embodiment, an etchant having an etching rate for removing the second semiconductor layer 103 greater than that for removing the first semiconductor layer 102 is applied for performing the wet etching process 201, whereby the portion of the second semiconductor layer 103 that is not encapsulated by the patterned photoresist layer 205 can be removed to form the second space 202 passing through the stack structure 10 and dividing the second semiconductor layer 103 into a third region 203 and a fourth region 204 (see FIG. 2B and FIG. 2B′).

Subsequently, the remaining portion of the first semiconductor layer 102 is partially removed to form a second floating structure 208 crossing the second space 202, a second source region 209 stacking on the third region 203, and a second drain region 210 stacking on the fourth region 204, wherein the second floating structure 208 connects the second source region 209 and the second drain region 210. In the present embodiment, a patterned photoresist layer 211 is formed to cover the n-type MOS transistor 11 and portions of the remaining first semiconductor layer 102 and the remaining second semiconductor layer 103 but not fill the second space 202, whereby a portion of the top surface 102a of the remaining first semiconductor layer 102 is exposed from the second space 202 (see FIG. 2C and FIG. 2C′).

An anisotropic etching process 212 (see FIG. 2C and FIG. 2C′), such as a RIE process or other dry etching process, is then performed to remove the portion of the remaining first semiconductor layer 102 that are not covered by the patterned photoresist layer 211, whereby the second floating structure 208, the second source region 209 and the second drain region 210 are defined in the remaining first semiconductor layer 102. In the present embodiment, the second floating structure 208 comprises a plurality of bridge portions 208a laterally extending from a sidewall 209a of the second source region 209 crossing the second space 202 to connect to a side wall 210a of the first drain region 210 (see FIG. 2D and FIG. 2D′). In some embodiments of the present invention, each of the bridge portions 208a may have a triangular cross-section, a rectangular cross-section or a trapezoidal cross-section. In the present embodiment, each of the bridge portions 208a has a trapezoidal cross-section.

In some embodiments of the present invention, after the anisotropic etching process 212 is carried out, an over etching process 213 is performed to remove a portion of the first floating structure 208. In the present embodiment, the over etching process 213 preferably is an isotropic etching process, and each of the bridge portions 208a may be annularly thinned down by the over etching process 213. In other words, the diameter of the bridge portions 208a can be reduced after the over etching process 213 is carried out, and each of the bridge portions 208a may not vertically extends beyond the sidewall 209a of the second source region 209 and the side wall 210a of the second drain region 210 (see FIG. 2E and FIG. 2E′).

In the present invention, the over etching process 213 may improve the performance of the transistor structure 200, when there is a lattice mismatched interface formed between the first semiconductor layer 102 and the second semiconductor layer 103, since the over etching process 213 can remove a portion of the first semiconductor layer 102 having the lattice mismatched interface that may provide tensile strain and retard hold carriers migrating through the bridge portions 208a serving as channels of the subsequently formed p-type MOS transistor 12.

Subsequently, a second gate structure 214 is formed to surround the second floating structure 208, wherein the second gate structure 214 comprises a gate dielectric layer 214a and a gate electrode layer 214b. For example, the gate dielectric layer 214a may be a high-k dielectric layer and the gate electrode layer 214b may be a metal or conductive compound layer. In the present embodiment, an ALD process (not shown) is performed to form a GeO₂ layer, an Al₂O₃ layer and a TiN layer stacking in sequence and surrounding each of the bridge portions 208a of the second floating structure 208, wherein the GeO₂ layer serves as a buffer layer, the Al₂O₃ layer serves as the gate dielectric layer 214a and the TiN layer serves as the gate electrode layer 214b.

After the second gate structure 214 is formed, at least one doping process (not shown) is performed to implant a plurality of p-type dopants, such as bromic (B) ions, into the second source region 209 and the second drain region 210, meanwhile the transistor structure 200 having an n-type MOS transistor 11 and a p-type MOS transistor 21 is formed (see FIG. 2F and FIG. 2F′).

In some embodiments of the present invention, some downstream process may be performed to form interconnects or wires (not shown) either on the first semiconductor layer 102 or on the second semiconductor layer 103, or even on both of them to integrate the n-type MOS transistor 11 and the p-type MOS transistor 21 into a complementary metal oxide semiconductor (CMOS).

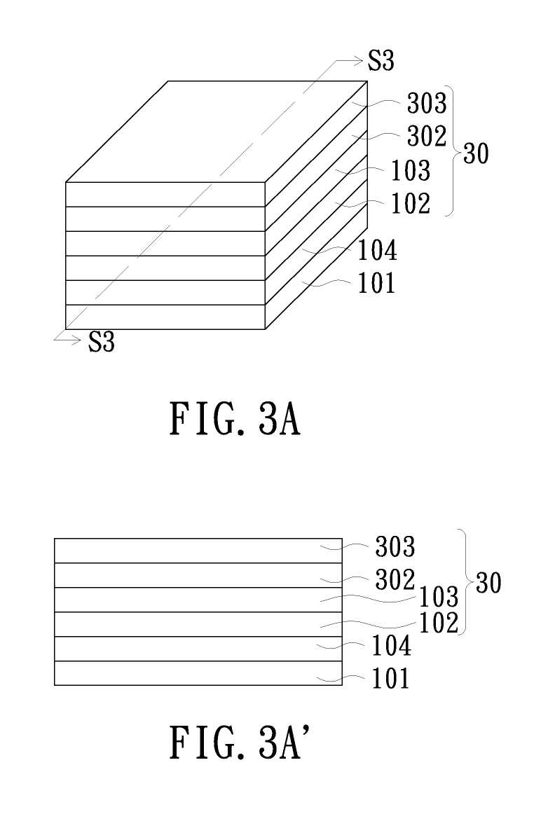

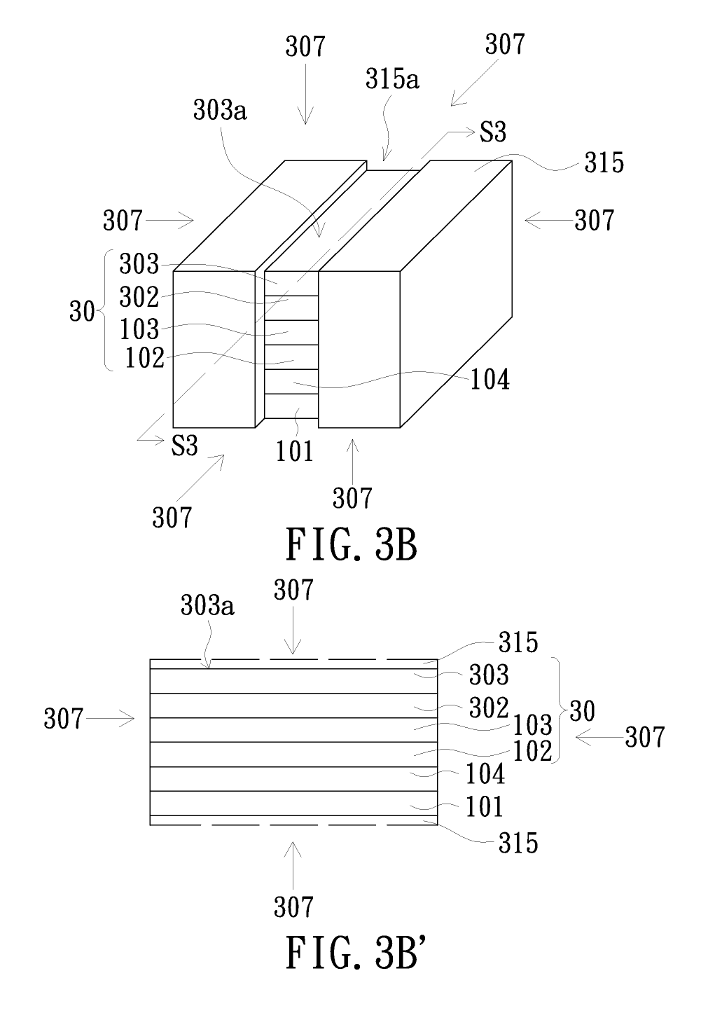

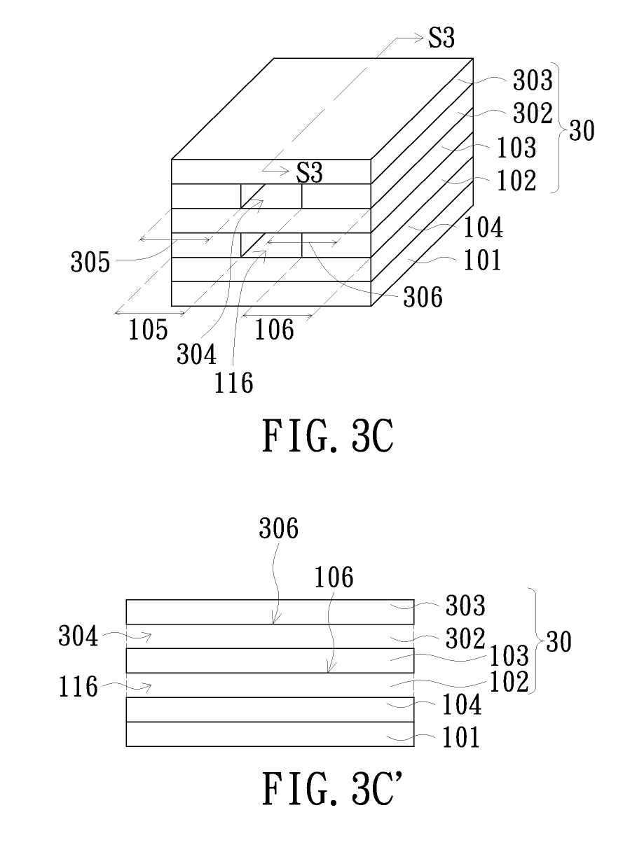

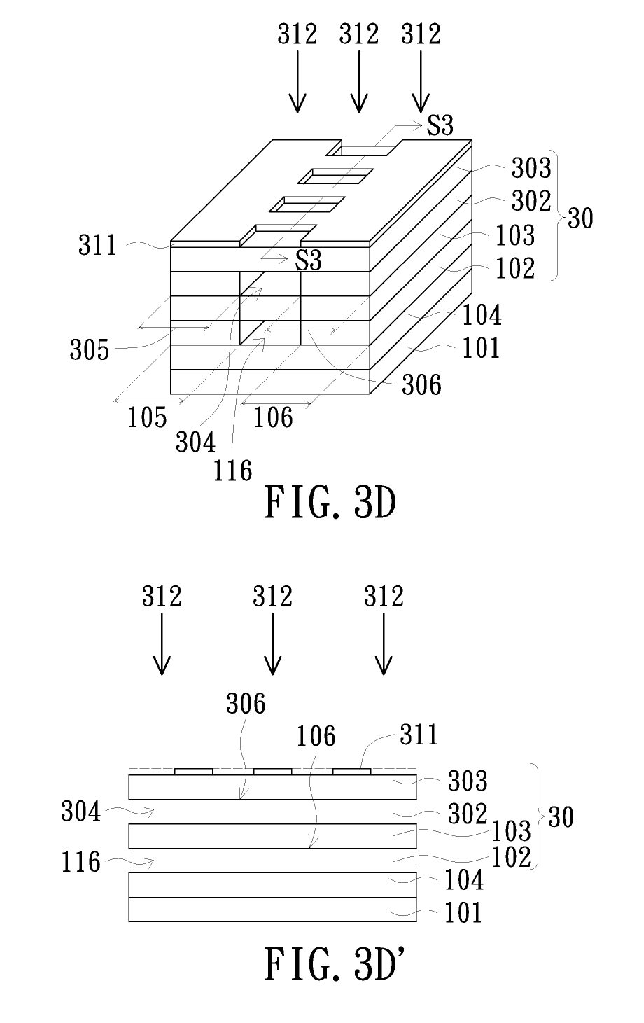

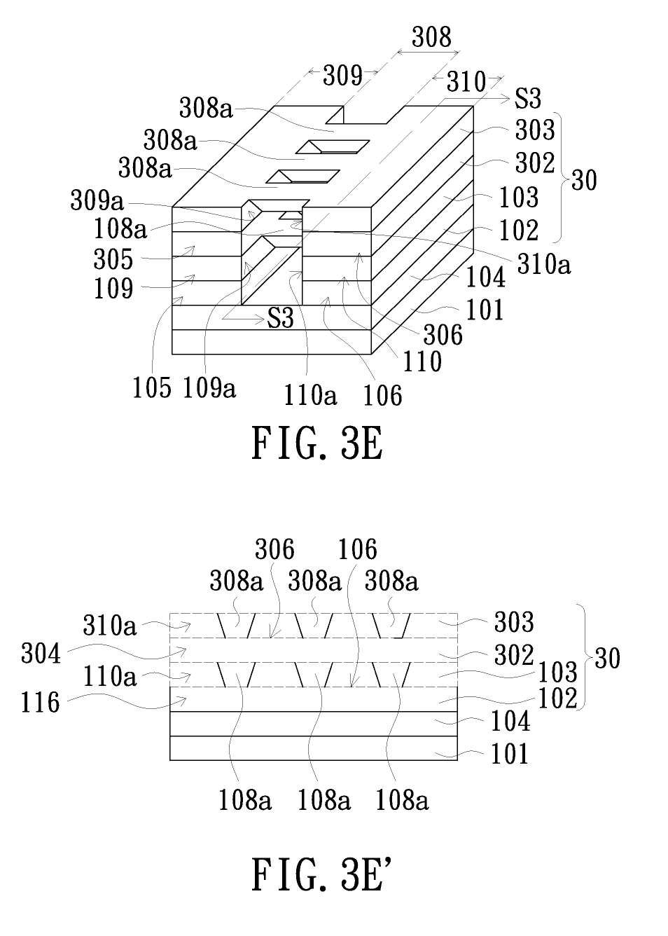

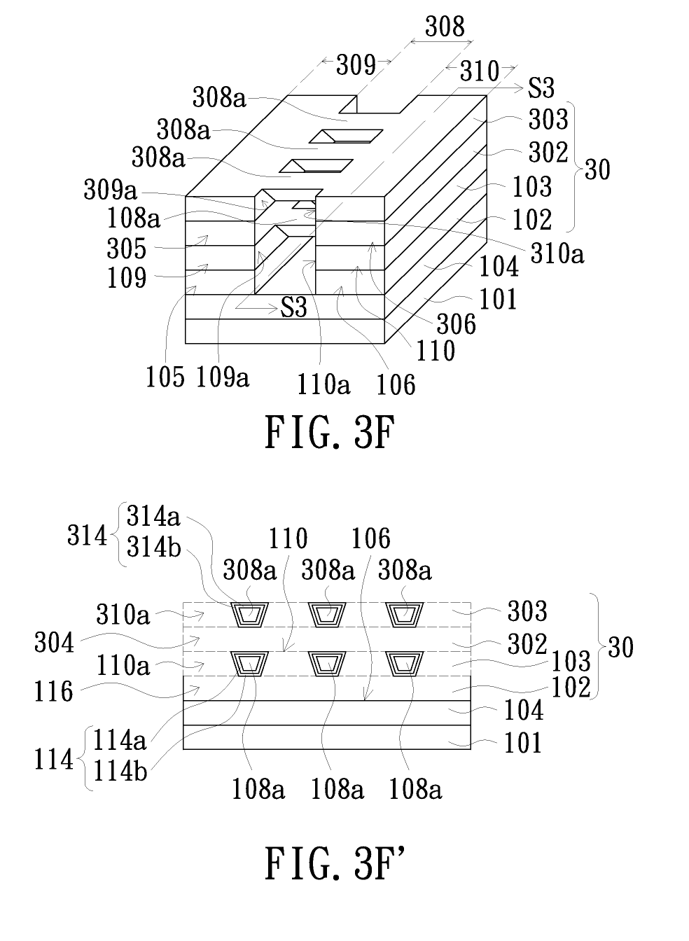

FIGS. 3A-3F are perspective views of the processing structures illustrating a method for fabricating a transistor structure 300 in accordance with still another embodiment of the present invention. FIGS. 3A′-3F′ are cross-sectional views taken along the cross-sectional line S3 of the FIGS. 3A-3F.

The structure of the transistor structure 300 is similar to that of the transistor structure 100 except that the transistor structure 300 further comprises still another MOS transistor 31 aligned to the MOS transistors 11 formed in another two semiconductor layers stacked on the second semiconductor layer 103 simultaneous to the fabricating process for fabricating the underlying MOS transistor 100. Thus the similar elements are illustrated by similar reference numbers.

For example, in the present embodiment, the process for fabricating the transistor structure 300 comprises steps as follows. Firstly, a substrate 101 is provided and a stacked structure 30 comprising a first semiconductor layer 102, a second semiconductor layer 103, a third semiconductor layer 302, a fourth semiconductor layer 303 is then formed on the substrate 101 (see FIG. 3A and FIG. 3A′).

Since the structure of the third semiconductor layer 302 and the fourth semiconductor layer 303 as well as the material for forming the same are identical to that of the first semiconductor layer 102 and the second semiconductor layer 103 depicted in FIG. 1A and 1A′, thus the structure and the material thereof will not be redundantly described therein.

In the present embodiment, the third semiconductor layer 302 and the fourth semiconductor layer 303 are formed simultaneous to the epitaxial growth process used to form the first semiconductor layer 102 and the second semiconductor layer 103, and the materials composing the third semiconductor layer 302 and the fourth semiconductor layer 303 are identical to the materials composing the first semiconductor layer 102 and the second semiconductor layer 103.

Next, the first semiconductor layer 102 and the third semiconductor layer 302 are partially removed to form a first space 116 and a third space 304 in the first semiconductor layer 102 and the third semiconductor layer 302 respectively, wherein the first space 116 divides the first semiconductor layer 102 into a first region 105 and a second region 106, and the third space 304 divides the third semiconductor layer 302 into a fifth region 305 and a sixth region 306. In the present embodiment, a patterned photoresist layer 315 having a slot opening 315a is formed to partially encapsulate the stacked structure 30 that is constituted by the first semiconductor layer 102, the second semiconductor layer 103, the third semiconductor layer 302 and the fourth semiconductor layer 303, whereby a top surface 303a of the fourth semiconductor layer 303 and portions of sidewalls of the first semiconductor layer 102, the second semiconductor layer 103, the third semiconductor layer 302 and the fourth semiconductor layer 303 are exposed through the slot opening 315a (see FIG. 3B and FIG. 3B′).

A wet etching process 307 (see FIG. 3B and FIG. 3B′) is then performed to remove a portion of the first semiconductor layer 102 and a portion of the third semiconductor layer 302. In the present embodiment, an etchant having an etching rate for removing the first semiconductor layer 102 and the third semiconductor layer 302 greater than that for removing the second semiconductor layer 103 and the fourth semiconductor layer 303 is applied for performing the wet etching process 307, whereby the portions of the first semiconductor layer 102 and the third semiconductor layer 302 that are not encapsulated by the patterned photoresist layer 307 can be removed to form the two tunnels (the first space 116 and the third space 304) respectively passing through the stack structure 30. As a result, the first semiconductor layer 102 is divided into a first region 105 and a second region 106 by the first space 116, and the third semiconductor layer 302 is divided into a fifth region 305 and a sixth region 306 by the third space 304 (see FIG. 3C and FIG. 3C′). In a preferred embodiment, the first space 116 aligns to the third space 304.

Subsequently, the second semiconductor layer 103 and the fourth semiconductor layer 303 are then partially removed respectively to identify a first floating structure 108, a first source region 109 and a first drain region 110 on the second semiconductor layer 103 and to identify a third floating structure 308, a third source region 309 and a third drain region 310 on the fourth semiconductor layer 303. Wherein, the first source region 109 and the first drain region 110 are respectively stacked on the first region 105 and second region 106; the first floating structure 108 crosses the first space 116 and connects the first source region 109 and the first drain region 110; the third source region 309 and the second drain region 310 are respectively stacked on the fifth region 305 and sixth region 306; and the third floating structure 308 crosses the third space 304 and connects the third source region 309 and the fourth drain region 310. (see FIG. 3E and FIG. 3E′).

In the present embodiment, a patterned photoresist layer 311 is formed to partially cover the stacked structure 30 and expose portions of the fourth semiconductor layer 303 that are overlapped with the second space 304. An anisotropic etching process 312 (see FIG. 3D and FIG. 3D′), such as a RIE process or other dry etching process, is then performed to remove the portion of the fourth semiconductor layer 303 and the portion of the second semiconductor layer 103 that are not covered by the patterned photoresist layer 311, whereby the second semiconductor layer 103 can be divided in to the first floating structure 108, the first source region 109 and the first drain region 110; and the fourth semiconductor layer 303 can be divided in to the third floating structure 308, the third source region 309 and the third drain region 310.

Referring to FIG. 3E and FIG. 3E′, the third floating structure 308 comprises a plurality of bridge portions 308a and each of which laterally extends from a sidewall 309a of the third source region 309 crossing the first space 116 to connected to a side wall 310a of the third drain region 110. In some embodiments of the present invention, each of the bridge portions 308a may have a triangular cross-section, a rectangular cross-section or a trapezoidal cross-section. In the present embodiment, each of the bridge portions 308a has a trapezoidal cross-section and aligns to one of the bridge portions 108a of the first floating structure 108.

In some embodiments of the present invention, after the anisotropic etching process 312 is carried out, an over etching process 313 is performed to remove portions of the first floating structure 108 and third floating structure 308. In the present embodiment, the over etching process 313 preferably is an isotropic etching process, and each of the bridge portions 108a and 308a may be annularly thinned down by the over etching process 313. In other words, the diameter of the bridge portions 108a and 308a can be reduced after the over etching process 313 is carried out; each of the bridge portions 108a and 308a may not vertically extends beyond the sidewall 109a of the first source region 109 and the side wall 110a of the first drain region 110; and each of the bridge portions 308a may not vertically extends beyond the sidewall 309a of the third source region 309 and the side wall 310a of the third drain region 310. Since similar over etching process, such as the over etching process 113 or 213, has been taught above, thus the detail steps of the over etching process 313 are not redundantly described.

Subsequently, a first gate structure 114 and a third gate structure 314 are formed to surround the first floating structure 108 and the third floating structure 308, wherein the first gate structure 114 comprises a gate dielectric layer 114a and a gate electrode layer 114b and the third gate structure 314 comprises a gate dielectric layer 314a and a gate electrode layer 314b. For example, in some embodiments of the present invention, the gate dielectric layer 114a and 314a may be a high-k dielectric layer and the gate electrode layer 114b and 314b may be a metal or conductive compound layer. In the present embodiment, an in-situ ALD process (not shown) may be performed to form a GeO₂ layer, an Al₂O₃ layer and a TiN layer stacking in sequence and surrounding each of the bridge portions 108a of the first floating structure 108 and the bridge portions 308a of the third floating structure 308, wherein the GeO₂ layer serves as a buffer layer, the Al₂O₃ layer serves as the gate dielectric layer 114a and 314a and the TiN layer serves as the gate electrode layer 114b and 314b.

After the first gate structure 114 and the third gate structure 314 are formed, at least one doping process (not shown) is performed to implant a plurality of n-type dopants, such as P ions or As ions, into the first source region 109, the second source region 309, the first drain region 110 and the third drain region 310, meanwhile the transistor structure 300 having two n-type MOS transistors 11 and 31 is formed (see FIG. 3F and FIG. 3F′).

Similarly, p-type MOS transistors may be integrated in the transistor structure 300 to form a CMOS structure. In addition, the transistor structure 300 may comprises more semiconductor layers and integrate more MOS transistors formed in these semiconductor layers.

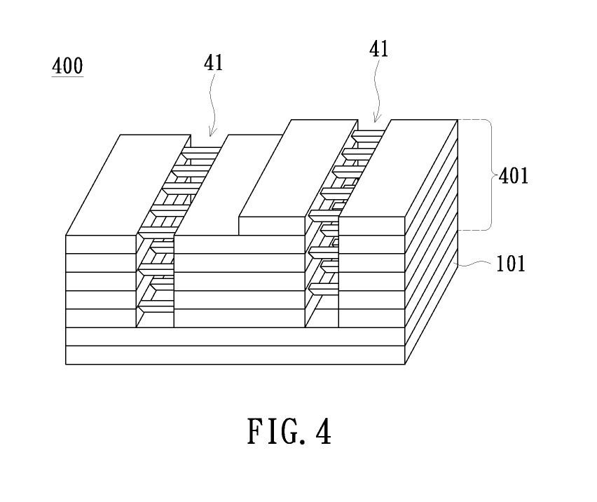

For example, FIG. 4 is a perspective view of a transistor structure 400 in accordance with still another embodiment of the present invention. In the present embodiment, the transistor structure 400 further comprises a plurality of semiconductor layers (totally referred to as) 401 stacked in sequence on the substrate 101 and a plurality of MOS transistors (totally referred to as) 41 are formed in these semiconductor layer 401. Since the process for forming a plurality of MOS transistor in a stacked structure composing a plurality of semiconductor layers has been taught by the aforementioned embodiments, thus the process for fabricating the transistor structure 400 will not be redundantly described therein.

In accordance with the aforementioned embodiments of the present invention, a transistor structure having at least one MOS transistor is provided. The process for fabricating the transistor structure comprises steps as follows. Firstly, a stacked structure constituted by a first semiconductor layer and a second semiconductor layer stacked in sequence is formed on a substrate. The first semiconductor layer is then partially removed to at least form a first space dividing the first semiconductor layer into a first region from a second region. Subsequently, the second semiconductor layer is also partially removed to form a source region stacked on the first region, a drain region stacked on the second region and a floating structure crossing the first space. Next, a first gate structure surrounding the first floating structure is formed. Since each MOS transistor involved in the transistor structure can be formed merely by steps of patterning two semiconductor layers formed and stacked in sequence on the subtract and performing a gate structure deposition process without applying a silicon on insulator (SOI) substrate, thus it is not requiring a complex procedure as compared to that for fabricating a conventional transistor structure. Such that, the process for fabricating the transistor structure can be simplified and the manufacturing cost thereof can be reduced.

In addition, another MOS transistor also formed in the first semiconductor layer and the second semiconductor layer may be further involved in the transistor structure by performing a similar fabricating process, and still another or more MOS transistor aligning to these two MOS transistors formed in the stacked structure can be further formed in other semiconductor layers stacked on the stacked structure simultaneous to the fabricating process for fabricating the underlying MOS transistor. As a result, more MOS transistors can be further integrated in the transistor structure by the simplified and less expense manufacturing process.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A transistor structure, comprising:
a substrate;
a first semiconductor layer formed on the substrate and having a first space dividing the first semiconductor layer into a first region and a second region;
a second semiconductor layer stacked on the first semiconductor layer, comprising:
a first source region, stacked on the first region;
a first drain region, stacked on the second region; and
a first floating structure crossing the first space and connecting the first source region and the first drain region;
wherein the first semiconductor layer has a first type conductivity and the second semiconductor layer has a second type conductivity.

2. The transistor structure according to claim 1, further comprising a germanium (Ge) epitaxial film as a buffer layer between the substrate and the first semiconductor layer.

3. The transistor structure according to claim 1, wherein the first semiconductor layer comprises germanium (Ge) or Ge-based materials including germanium antimonide (GeSb) or germanium telluride (GeTe).

4. The transistor structure according to claim 1, wherein the second semiconductor layer comprises III-V compound semiconductor materials including gallium arsenide (GaAs) or gallium indium arsenide (InGaAs).

5. The transistor structure according to claim 1, wherein the first floating structure comprises a plurality of bridge portions laterally extending from a sidewall of the first source region crossing the first space to connect to a side wall of the first drain region.

6. The transistor structure according to claim 1, wherein the first floating structure is surrounded by a first gate structure comprising a gate dielectric layer and a gate electrode layer.

7. The transistor structure according to claim 6, wherein the gate dielectric layer comprises a high-k dielectric material and the gate electrode layer comprises metal or conductive compound.

8. A transistor structure, comprising:
a substrate;
a first semiconductor layer formed on the substrate;
a second semiconductor layer stacked on the first semiconductor layer, the second semiconductor layer having a second space dividing the second semiconductor layer into a third region and a fourth region:
wherein the first semiconductor layer comprises:
a second source region stacked under the third region;
a second drain region stacked under the fourth region; and
a second floating structure crossing the second space and connecting the second source region and the second drain region;
wherein the first semiconductor layer has a first type conductivity and the second semiconductor layer has a second type conductivity.

9. The transistor structure according to claim 8, further comprising a germanium (Ge) epitaxial film as a buffer layer between the substrate and the first semiconductor layer.

10. The transistor structure according to claim 8, wherein the first semiconductor layer comprises germanium (Ge) or Ge-based materials including germanium antimonide (GeSb) or germanium telluride (GeTe).

11. The transistor structure according to claim 8, wherein the second semiconductor layer comprises III-V compound semiconductor materials including gallium arsenide (GaAs) or gallium indium arsenide (InGaAs).

12. The transistor structure according to claim 8, wherein the second floating structure comprises a plurality of bridge portions laterally extending from a sidewall of the second source region crossing the second space to connect to a side wall of the second drain region.

13. The transistor structure according to claim 8, wherein the second floating structure is surrounded by a second gate structure comprising a gate dielectric layer and a gate electrode layer.

14. The transistor structure according to claim 13, wherein the gate dielectric layer comprises a high-k dielectric material and the gate electrode layer comprises metal or conductive compound.

15. A transistor structure having at least one first transistor with a first type conductivity channel and at least one second transistor with a second type conductivity channel, the transistor structure comprising:
a substrate;
a first semiconductor layer formed on the substrate;
a second semiconductor layer stacked on the first semiconductor layer;
wherein, in the first transistor,
the first semiconductor layer has a first space dividing the first semiconductor layer into a first region and a second region;
the second semiconductor layer comprises:
a first source region, stacked on the first region;
a first drain region, stacked on the second region; and
a first floating structure crossing the first space and connecting the first source region and the first drain region;
wherein, in the second transistor,
the second semiconductor layer has a second space dividing the second semiconductor layer into a third region and a fourth region;
the first semiconductor layer comprises:
a second source region stacked under the third region;
a second drain region stacked under the fourth region; and
a second floating structure crossing the second space and connecting the second source region and the second drain region;
wherein the first semiconductor layer has a first type conductivity and the second semiconductor layer has a second type conductivity.

16. The transistor structure according to claim 15, further comprising a germanium (Ge) epitaxial film as a buffer layer between the substrate and the first semiconductor layer.

17. The transistor structure according to claim 15, wherein the first semiconductor layer comprises germanium (Ge) or Ge-based materials including germanium antimonide (GeSb) or germanium telluride (GeTe).

18. The transistor structure according to claim 15, wherein the second semiconductor layer comprises III-V compound semiconductor materials including gallium arsenide (GaAs) or gallium indium arsenide (InGaAs).

19. The transistor structure according to claim 15, wherein the first floating structure comprises a plurality of bridge portions laterally extending from a sidewall of the first source region crossing the first space to connect to a side wall of the first drain region and the second floating structure comprises a plurality of bridge portions laterally extending from a sidewall of the second source region crossing the second space to connect to a side wall of the second drain region.

20. The transistor structure according to claim 15, wherein the first floating structure and the second floating structure are surrounded by a first gate structure comprising a gate dielectric layer and a gate electrode layer.

21. The transistor structure according to claim 20, wherein the gate dielectric layer comprises a high-k dielectric material and the gate electrode layer comprises metal or conductive compound.
